(19) United States
(12) Patent Application Publication
(10) Pub. No.: US 2014/0299307 A1
(43) Pub. Date: Oct. 9, 2014

(54) TERMINAL APPARATUS OF SUPERCONDUCTING DEVICE

(71) Applicant: LS Cable & System Ltd., Anyang-si (KR)

(72) Inventors: Heo-Gyung SUNG, Gumi-si (KR); Hyun- Man JANG, Hwaseong-si (KR); Chang-Youl CHOI, Ansan-si (KR)

(73) Assignee: LS Cable & System Ltd., Anyang-si (KR)

(21) Appl. No.: 14/094,882

(22) Filed: Dec. 3, 2013

(30) Foreign Application Priority Data
Jan. 23, 2013 (KR) 10-2013-0007471

(51) Int. Cl. H01L 39/04; F17C 13/02

(52) U.S. Cl. CPC H01L 39/04; F17C 13/025; F17C 13/026
USPC 165/253; 62/49.2

(57) ABSTRACT

The present invention relates to a terminal apparatus of a superconducting device that is capable of minimizing the use of dividing members for dividing a liquid refrigerant, a vapor refrigerant or a room temperature insulating material, thereby preventing sealing members like O-rings mounted on the respective dividing members from being damaged.

### CROSS REFERENCE TO RELATED APPLICATION

This application claims the benefit of the Patent Korean Application No. 10-2013-0007471, filed on Jan. 23, 2013, which is hereby incorporated by reference as if fully set forth herein.

### BACKGROUND OF THE INVENTION

1. Field of the Invention

The present invention relates to a terminal apparatus of a superconducting device, and more particularly, to a terminal apparatus of a superconducting device that is capable of minimizing the use of dividing members for dividing a liquid refrigerant, a vapor refrigerant or a room temperature insulating material, thereby preventing sealing members like O-rings mounted on the respective dividing members from being damaged.

2. Background of the Related Art

A superconductor has zero electric resistance at a given temperature and thus provides a high current transfer capacity even at a low voltage.

A superconducting device with such superconductor forms and maintains a cryogenic temperature environment by cooling a refrigerant like nitrogen and/or forms a vacuum layer through insulation. An example of the superconducting device is a superconducting cable.

The current transmitted through the superconducting device is connected to a conductor wire being at a room temperature environment through a terminal apparatus of the superconducting device.

So as to avoid the problems caused when the environment where the superconductor is exposed is suddenly changed from a cryogenic temperature environment to a room temperature environment, the terminal apparatus of the superconducting device connects the superconductor to the conductor wire and draws the connected conductor wire to the room temperature environment, while ensuring sufficient temperature gradient between the cryogenic temperature environment and the room temperature environment.

Accordingly, the terminal apparatus is divided into a room temperature part, a temperature gradient part and a cryogenic temperature part in the direction from the upper end to the lower end thereof in accordance with temperatures. The cryogenic temperature part contains a cryogenic temperature liquid refrigerant therein, the temperature gradient part contains a vapor refrigerant located above the liquid refrigerant therein in such a manner to have the temperature gradient between a cryogenic temperature and a room temperature, and the room temperature part A is at the room temperature environment.

As a result, as the conductor wire connected to the superconductor is passed through the cryogenic temperature part, the temperature gradient part and the room temperature part, it is slowly exposed to the room temperature environment from the cryogenic temperature environment.

Like this, the terminal apparatus of the superconducting device reduces the occurrence of the insulation breakdown caused by the drastic temperature change, while supplying the current supplied from the superconductor to the conductor wire being at a room temperature.

However, conventional terminal apparatus of a superconducting device have the following problems.

As one of prior art documents, there is disclosed Korean Patent Application No. 10-2011-0005534 (hereinafter, referred to as “first prior art document”) wherein a terminal apparatus of a superconducting device divides a cryogenic temperature part and a temperature gradient part by a sealing plate, thereby physically dividing a cryogenic temperature liquid refrigerant and a vapor refrigerant having temperature gradient. In this case, however, it is not easy to ensure the tightness or durability of the sealing plate exposed to the cryogenic temperature liquid refrigerant and a sealing member (O-ring and the like) mounted on the sealing plate, and further, it is not desirable that the cryogenic temperature liquid refrigerant and the vapor refrigerant are shielded from each other by an artificial structure.

Moreover, a second pipe body and a third pipe body containing the liquid refrigerant and the vapor refrigerant are formed unitarily with each other, and in this case, no problem occurs on the tightness or durability of the sealing member (O-ring and the like) mounted on the sealing plate. However, there is no method for controlling the liquid surface of the liquid refrigerant contained below the sealing plate. Even though the liquid refrigerant is contained under the sealing plate, that is, it is not desirable that the liquid refrigerant is directly contacted with the sealing plate.

According to the first prior art document, however, there is no method for preventing the liquid surface of the liquid refrigerant from being increased and directly contacted with the sealing plate.

Further, there is disclosed Korean Patent Application No. 10-2011-0085717 (hereinafter, referred to as “second prior art document”) wherein a terminal apparatus of a superconducting device improves the connection and insulation structures of a conductor wire in a temperature gradient part in such a manner to detachably mount the temperature gradient part, so as to improve the assembly, structural strength, and insulation strength of the temperature gradient part. In the same manner as the first prior art document, however, the second prior art document has the structure where a spacer member dividing a cryogenic temperature part and a temperature gradient part is exposed directly to a cryogenic temperature liquid refrigerant, so that it is not easy to ensure the tightness or durability of a sealing member (O-ring and the like) mounted on the spacer member and further there is no liquid surface location controlling method for preventing the liquid surface of the liquid refrigerant from being directly contacted with the spacer member.

Furthermore, there is disclosed Japanese Patent Application No. 2011-160641 (hereinafter, referred to as “third prior art document”) wherein a terminal apparatus of a superconducting device contains a liquid refrigerant layer on the lower part of an inside pressure container and refrigerant gas contained on the upper part thereof. According to the third prior art document, no shielding part like a sealing plate or spacer member is located between the cryogenic temperature part containing the liquid refrigerant therein and the temperature gradient part containing vapor refrigerant, so that there is no problem caused when the sealing plate or the spacer member and the sealing member like O-ring mounted on the sealing plate or the spacer member are exposed directly to the cryogenic temperature liquid refrigerant. According to the third prior art document, a high voltage drawing part as the room temperature part is divided with the refrigerant gas layer contained in the temperature gradient part by a flange, but there is no method for controlling the liquid surface of the liquid refrigerant between the cryogenic temperature part and the temperature gradient part.

If the liquid surface of the liquid refrigerant is abnormally increased, accordingly, the flange dividing the room temperature part and the temperature gradient part may be exposed to the cryogenic temperature liquid refrigerant, so that it is not easy to ensure the tightness or durability of the sealing member.

According to the third prior art document, further, in the state where the conductor wire and bushing provided on the cryogenic temperature part and the temperature gradient part are passed through the flange and extended to the room temperature part, there is no structure for detachably mounting the room temperature part on the temperature gradient part, so that it is not easy to connect with other external devices.

Moreover, in the state where no dividing members such as partition, flange or spacer are provided between the cryogenic temperature part where the liquid refrigerant is contained and the temperature gradient part in which the vapor refrigerant is contained, the third prior art document just ensures the tightness or durability of the sealing member.

While removing any dividing members such as partition, flange or spacer are provided between the cryogenic temperature part where the liquid refrigerant is contained and the temperature gradient part in which the vapor refrigerant is contained, accordingly, a method for artificially controlling the liquid surface of the liquid refrigerant has been disclosed in Japanese Patent Application No. 2011-40705 (hereinafter, referred to as “fourth prior art document”).

According to the fourth prior art document, that is, the terminal apparatus of a superconducting device has a liquid surface adjusting means for controlling the liquid surface of the liquid refrigerant in a refrigerant container, and if the liquid surface is increased, it forcedly supplies a vapor refrigerant to the temperature gradient part through the liquid surface adjusting means, thereby preventing the liquid surface of the liquid refrigerant from approaching the cryogenic temperature part and the temperature gradient part. If a separate gas supply pipe is formed on the temperature gradient part, however, the reliability of the tightness of the temperature gradient part may be deteriorated.

In the same manner as above, according to the fourth prior art document, in the state where the conductor wire and bushing provided on the cryogenic temperature part and the temperature gradient part are extended to the room temperature part, there is no structure for detachably mounting the room temperature part on the temperature gradient part, so that it is not easy to connect with other external devices.

On the other hand, there is disclosed Korean Patent Application No. 10-2007-0102651 (hereinafter, referred to as “fifth prior art document”) wherein a terminal apparatus of a superconducting device reduces the gap between the inner surface of the refrigerant container and the outer peripheral surface of a bushing to control the liquid surface to be naturally located at a temperature gradient part, but since it is applied just to a specific experimental condition, it is not applicable to general conditions, thereby failing to ensure the tightness or durability of a flange. In the same manner as above, there is no mention of the liquid surface location adjusting means for decreasing the location of liquid surface of the liquid refrigerant, thereby causing the above-mentioned problems.

In the same manner as above, according to the fifth prior art document, in the state where the conductor wire and bushing provided on the cryogenic temperature part and the temperature gradient part are extended to the room temperature part, there is no mention of a structure for detachably mounting the room temperature part on the temperature gradient part, so that it is not easy to connect with other external devices or there is a need for a separate connection box.

### SUMMARY OF THE INVENTION

In accordance with an aspect of the present invention, the above and other objects can be accomplished by the provision of a terminal apparatus of a superconducting device, comprising a refrigerant container having a cryogenic temperature part formed in the lower part thereof, the cryogenic temperature part containing a liquid refrigerant therein, and a temperature gradient part formed above the cryogenic temperature part, the temperature gradient part containing a vapor refrigerant having temperature gradient therein, at least one liquid level controlling unit mounted on the outer periphery of the refrigerant container, at least one sensing unit mounted on the outer periphery of the refrigerant container for sensing the temperature or pressure of the refrigerant container or the temperature or pressure of the refrigerant contained in the refrigerant container, a controller for controlling the liquid level controlling unit in accordance with the liquid level based on the sensing signal of the sensing unit, a sealing member for sealing the top end of the refrigerant container, a room temperature part housing divided with the refrigerant container and having insulating oil or insulating gas contained therein and forming a room temperature part and a conductor wire connected to a superconductor of the superconducting device into the liquid refrigerant in the refrigerant container in such a manner to be passed through the sealing member and extended to the room temperature part housing.

The sensing unit may comprise a temperature sensor mounted on the refrigerant container.

The temperature sensor may measure the temperature of the surface of the refrigerant container.

The temperature sensor may be provided plurally, and at least one temperature signals of the plural sensors may be mounted on the temperature gradient part of the refrigerant container.

The sensing unit may comprise a pressure sensor mounted on the refrigerant container.

Two or more pressure sensors may be mounted on different positions from each other.

At least one pressure sensor may be mounted on the cryogenic temperature part and the temperature gradient part, respectively, for sensing the pressures of the liquid refrigerant and vapor refrigerant contained in the refrigerant container.

The pressure sensor mounted on the cryogenic temperature part may be located at a position where the pressure of the liquid refrigerant existing on the lowest area of the cryogenic temperature part is sensed.

The controller may determine the liquid level of the liquid refrigerant on the basis of the pressure difference sensed by the pressure sensors mounted on the cryogenic temperature part and the temperature gradient part.

The refrigerant container may be sealed by the sealing member, and the room temperature part housing is mounted on the sealing member.

The terminal apparatus of a superconducting device may further comprise a vacuum container for surrounding the refrigerant container in such a manner to allow the region beneath the top end of the refrigerant container to be exposed to the outside.

The liquid level controlling unit may comprise at least one electric heaters mounted on the outer peripheral surface of the refrigerant container.

The electric heaters may be mounted spaced apart from each other at different heights of the temperature gradient part.

The controller may control the electric heaters to maintain the liquid surface of the liquid refrigerant in the refrigerant container within a predetermined range.

The lower end of the predetermined range may be located at the height of the foil electrode disposed at the uppermost position among a plurality of foil electrodes mounted on a busing located on the lower part of the conductor wire.

The upper end of the predetermined range may be located at the height of the lower end of the electric heater disposed at the lowermost position among the electric heaters mounted on the temperature gradient part.

And in accordance with an aspect of the present invention, the above and other objects can be accomplished by the provision of a terminal apparatus of a superconducting device, comprising a refrigerant container containing a liquid refrigerant contained in the lower part thereof and a vapor refrigerant contained above the liquid refrigerant, at least one electric heaters mounted on the outer periphery of the refrigerant container, at least one temperature sensors mounted on the outer periphery of the refrigerant container for sensing the temperature of the refrigerant container or the temperature of the refrigerant contained in the refrigerant container, a controller for controlling the electric heaters in accordance with the liquid level based on the sensing signal through the temperature sensor, a first conductor wire connected to a superconductor of the superconducting device in such a manner to have the lower part submerged into the liquid refrigerant in the refrigerant container and the upper part extended to the upper part of the refrigerant container in which the vapor refrigerant is contained, a sealing member for sealing the top end of the refrigerant container, a second conductor wire detachably connected to the first conductor wire by the sealing member in such a manner to be extended upwardly and a room temperature part housing detachably mounted on the sealing member to surround the second conductor wire and having insulating oil or insulating gas contained therein.

The controller may operate the electric heaters if the temperature sensed by the temperature sensor is decreased under a predetermined temperature.

The electric heaters may be mounted plurally on the outer peripheral surface of the refrigerant container, and the temperature sensors are mounted plurally adjacent to the electric heaters on the outer peripheral surface of the refrigerant container.

The controller may control the electric heaters for the operating start point, operating time, and the heating value per unit time of at least one electric heater among the electric heaters to be different from those of the other electric heaters or for the operating start points, operating time, and the heating values per unit time of the electric heaters to be same as each other.

The terminal apparatus of a superconducting device may further comprise a vacuum container for surrounding the refrigerant container in such a manner for the region beneath the top end of the refrigerant container to be exposed to the outside, thereby allowing the space of the refrigerant container where the liquid refrigerant is contained and a part of the space where the vapor refrigerant is contained to be vacuum-insulated, and wherein at least one electric heater among the electric heaters is mounted on the outer peripheral surface of the refrigerant container exposed to the outside of the vacuum container.

The controller may control the electric heater mounted on the outer peripheral surface of the refrigerant container exposed to the outside of the vacuum container for the operating time thereof to be longer than that of the other electric heaters.

The controller may control the electric heater mounted on the outer peripheral surface of the refrigerant container exposed to the outside of the vacuum container for the operating start point thereof to be more rapid than those of the other electric heaters.

The controller may control the electric heater mounted on the outer peripheral surface of the refrigerant container exposed to the outside of the vacuum container for the heating value per unit time thereof to be larger than those of the other electric heaters.

The terminal apparatus of a superconducting device may further comprise at least one pressure sensors mounted on the outer periphery of the refrigerant container for sensing the pressure of the liquid refrigerant or the pressure of the vapor refrigerant contained in the refrigerant container.

The pressure sensors may be mounted on the position of the refrigerant container where the liquid refrigerant is contained and the space where the vapor refrigerant is contained, so as to sense the pressures of the liquid refrigerant and vapor refrigerant, and the controller determines the liquid level of the liquid refrigerant on the basis of the pressure difference sensed by the pressure sensors.

The sealing member may comprise a conductive connector disposed at the center part thereof to couple the first conductor wire and the second conductor wire to each other.

### BRIEF DESCRIPTION OF THE DRAWINGS

The above and other objects, features and advantages of the present invention will be apparent from the following detailed description of the preferred embodiments of the invention in conjunction with the accompanying drawings, in which:

FIG. 1 is a sectional view showing a terminal apparatus of a superconducting device according to a first embodiment of the present invention;

FIG. 2 is a sectional view showing a terminal apparatus of a superconducting device according to a second embodiment of the present invention;

FIG. 3 is a sectional view showing a terminal apparatus of a superconducting device according to a third embodiment of the present invention;

FIG. 4 is a sectional view showing a terminal apparatus of a superconducting device according to a fourth embodiment of the present invention;

FIG. 5 is a sectional view showing a terminal apparatus of a superconducting device according to a fifth embodiment of the present invention;

FIG. 6 is a sectional view showing a terminal apparatus of a superconducting device according to a sixth embodiment of the present invention; and

FIG. 7 is a block diagram showing the terminal apparatus of the superconducting device according to the present invention.

### DETAILED DESCRIPTION OF THE PREFERRED EMBODIMENT

Hereinafter, an explanation on a terminal apparatus of a superconducting device according to the preferred embodiments of the present invention will be in detail given with reference to the attached drawing. The explanation on the specific structure and functions are given just to define the preferred embodiments of the present invention, and the preferred embodiments of the present invention may be provided in various manners, which are not limited to the embodiments described below. In the description of the invention with reference to the attached drawings, further, the same components are indicated by the same reference numerals as each other, and for the brevity of the description, the explanation on their repeated features will be avoided.

According to the present invention, a terminal apparatus of a superconducting device does not need any dividing member for dividing a cryogenic temperature part in which a liquid refrigerant is contained and a temperature gradient part in which a vapor refrigerant is contained and also solves the problems caused when the liquid surface (or liquid level of the refrigerant) of the liquid refrigerant abnormally approaches a room temperature part.

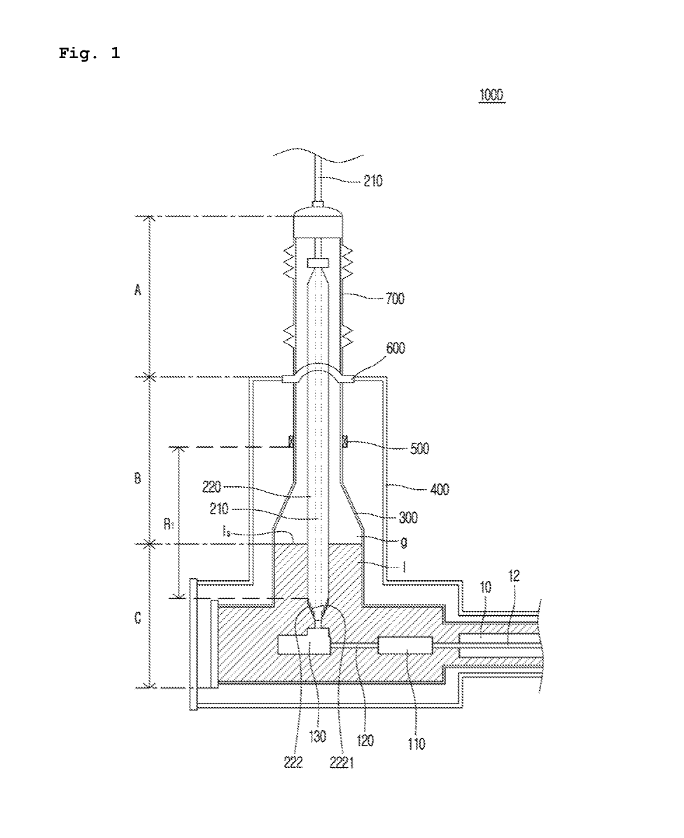

FIG. 1 is a sectional view showing a terminal apparatus of a superconducting device according to a first embodiment of the present invention.

A terminal apparatus 1000 of a superconducting device according to a first embodiment of the present invention includes: a cryogenic temperature part C containing a liquid refrigerant I in which a lower part of a conductor wire 210 is submerged therein, the conductor wire 210 being connected to a superconductor and having a bushing 220 fitted on the outer periphery thereof; a temperature gradient part B formed to be communicated with the cryogenic temperature part C and formed to contain a vapor refrigerant g therein in such a manner to have temperature gradient, in the state where the conductor wire 210 is extended upwardly from the cryogenic temperature part C; a room temperature part A divided with the temperature gradient part B and having the conductor wire 210 extended from the cryogenic temperature part C and the temperature gradient part B and drawn to the outside; and at least one liquid level controlling unit provided in the temperature gradient part B or the cryogenic temperature part C to control the liquid surface (or liquid level) of the liquid refrigerant contained in the cryogenic temperature part C to be located within a predetermined range.

The terminal apparatus 1000 of a superconducting device is divided into the cryogenic temperature part C wherein the conductor wire 210 connected to the superconductor constituting the superconducting device is submerged into the cryogenic temperature liquid refrigerant I, the temperature gradient part B wherein the conductor wire 210 is located in the vapor refrigerant g contained to have a given temperature gradient as the height of the liquid surface Is of the liquid refrigerant contained in the cryogenic temperature part C is increased, and the room temperature part A divided with the temperature gradient part B and formed to contain insulating oil or insulating gas therein at a room temperature environment, from which the conductor wire 210 is extended and drawn.

The cryogenic temperature part C contained with the cryogenic temperature liquid refrigerant and the temperature gradient part B contained with the vapor refrigerant are configured to communicate with each other, so that the liquid surface Is of the liquid refrigerant I contained in the cryogenic temperature part C can be increased in accordance with the temperature and internal pressure of the liquid refrigerant.

The cryogenic temperature part C and the temperature gradient part B are divided with each other in accordance with the liquid level Is of the liquid refrigerant contained in a refrigerant container 300.

The conductor wire 210 is connected to the superconductor 12. In this case, the connection of the conductor wire 210 to the superconductor 12 means both of the case where the conductor wire 210 is directly connected to the superconductor 12 by connection means like a connector, joint or other means and the case where the conductor wire 210 is indirectly connected to the superconductor 12 by adopting a connecting conductor 120 as will be described below.

That is, the end part of the superconductor 12 constituting the core of the superconducting device is connected to the connecting conductor 120 at a connection part 110, and the connecting conductor 120 connected through the connection part 110 to the superconductor 12 is electrically connected to the conductor wire 210 through the joint 130.

Even if not shown in FIG. 1, an insulating support material may be provided around the connection part 110 to remove the stress generated by thermal shrinkage.

The joint 130 provides a structure in which the connecting conductor 120 can be stably connected to the conductor wire 210, in spite of the horizontal shrinkage or tension of the connecting conductor 120 due to the temperature. For example, the joint 130 includes a flexible braided wire connecting member.

The conductor wire 210 connected to the joint 130 is arranged toward the top end of the refrigerant container 300.

The conductor wire 210 is made of a copper (Cu) material or aluminum (Al) material and has the bushing 220 fitted around the outer periphery thereof. Of course, the conductor wire 210 may be formed of a bare conductor having no bushing material mounted thereon.

The copper and aluminum are examples of the conductive materials like metals having low electrical resistance at a refrigerant temperature used in the superconducting device, for example, even at a liquid nitrogen temperature when liquid nitrogen is used as the refrigerant.

The bushing 220 is formed by coating an insulating material like ethylene propylene rubber or fiber reinforced plastic (FRP) on the outer periphery of a stainless pipe.

Further, the bushing 220 has a plurality of foil electrodes 2221 formed vertically along the slant surfaces formed on the top end part and the bottom end part 222 in the lengthwise direction on the outer periphery thereof, and the part on which the foil electrodes 2221 are formed has a tapered shape.

The foil electrodes 2221 located on the bushing 220 may be adapted as electric field mitigation means.

The liquid refrigerant I contained in the cryogenic temperature part C and the vapor refrigerant g contained in the temperature gradient part B are stored in the refrigerant container 300. The refrigerant container 300 is made of metals like stainless having excellent strength.

The refrigerant container 300 is divided into a lower part containing liquid refrigerant I and an upper part containing vapor refrigerant g in such a manner to have the temperature gradient thereof and the lower part of the conductor wire 210 is submerged into the liquid refrigerant I.

Further, the liquid surface Is of the liquid refrigerant I contained in the lower part of the refrigerant container 300 may be increased or decreased in accordance with the internal temperature or pressure of the liquid refrigerant. If the liquid refrigerant I is liquid nitrogen, the vapor refrigerant g is vapor nitrogen.

The terminal apparatus 1000 of the superconducting device according to the first embodiment of the present invention further includes a sealing member 600 for sealing the temperature gradient part B in such a manner to be divided with the room temperature part A.

The top end of the refrigerant container 300 has opened structure. And to seal the refrigerant container 300, the sealing member 600 is made of epoxy plastic having excellent cold resistance and corrosion resistance.

The room temperature part A is located above the temperature gradient part B and divided with the temperature gradient part B by the sealing member 600.

The conductor wire 210 is extendedly arranged at the inside of the room temperature part A, and the room temperature part A has a room temperature part housing 700 for surrounding the conductor wire 210, and the room temperature part housing 700 contains the insulating oil or insulating gas (air or SF6 gas the like) therein. The room temperature part housing 700 may be composed of polymer material.

In this manner, the conductor wire 210, which is passed through the room temperature part A, is drawn to the outside, while minimizing the impacts caused by the temperature changes.

The terminal apparatus 1000 of the superconducting device according to the first embodiment of the present invention does not have any separate flange member, partition or sealing material between the cryogenic temperature part C and the temperature gradient part B, thereby removing the problem that they are hardened or damaged through the exposure to the liquid refrigerant.

Accordingly, the height of the liquid surface Is on the upper part of the refrigerant container 300 containing liquid refrigerant and gas refrigerant is generally increased or decreased in accordance with the temperature or pressure of the liquid refrigerant I. Of course, the drastic changes of the temperature or pressure of the vapor refrigerant in the temperature gradient part B give some influences on the height of the liquid surface Is.

The terminal apparatus 1000 of the superconducting device according to the first embodiment of the present invention does not have any member adapted to divide the cryogenic temperature part C and the temperature gradient part B from each other. If the liquid surface Is of the liquid refrigerant I is raised abnormally, it reaches the sealing member 600 dividing the room temperature part A and the temperature gradient part B and sealing the temperature gradient part B. If the liquid refrigerant I at the cryogenic temperature state approaches the sealing member 600, the tightness or durability of the sealing member 600 or the O-ring thereof may be damaged. So as to maintain the liquid surface Is of the liquid refrigerant I contained in the refrigerant container 300 within a predetermined range, accordingly, a liquid level controlling unit is provided to adjust the liquid level Is of the liquid refrigerant I

In the conventional practices, the liquid level is adjusted by charging or drawing the refrigerant into or from the refrigerant container, which is not advantageous in keeping tightness.

The liquid level controlling unit may be a heater or cooler. According to the present invention, the heater as the liquid level controlling unit will be in detail described, and of course, the cooler is applicable to the present invention.

Accordingly, the terminal apparatus 1000 of the superconducting device according to the first embodiment of the present invention adopts a heater, especially, an electric heater as the liquid level controlling unit.

In more detail, the liquid level controlling unit is formed of at least one electric heater 500 mounted on the outer peripheral surface of the refrigerant container 300 forming the cryogenic temperature part C and the temperature gradient part B.

The electric heater 500 is mounted on the refrigerant container 300. In detail, the electric heater 500 is mounted on the outer peripheral surface of the refrigerant container 300, and the heat generated from the electric heater 500 is conducted to the refrigerant container 300 generally made of a metal material to allow the liquid nitrogen on the liquid surface to be vaporized, thereby decreasing the height of the liquid surface Is.

A vacuum container 400 is provided to surround the refrigerant container 300 so as to make the refrigerant container 300 vacuum-insulated.

The vacuum container 400 is configured to communicate with a vacuum insulation part of the superconducting device and to surround the lower part of the refrigerant container 300 as well as the refrigerant container 300.

In the first embodiment of the present invention as shown in FIG. 1, the vacuum container 400 is extended to the top part of the refrigerant container 300 to conduct the vacuum insulation of the refrigerant.

The electric heater 500, which is mounted on the refrigerant container 300, heats the refrigerant container 300 to adjust the liquid level Is of the liquid refrigerant I, thereby preventing the liquid surface Is of the liquid refrigerant I in the refrigerant container 300 from approaching the sealing member 600. The electric heater 500 is attached to the outer peripheral surface of the refrigerant container 300 and takes a shape of a band heater.

The electric heater 500 is selectively operated to maintain the liquid surface Is of the liquid refrigerant I at the predetermined range R1.

In this case, so as to prevent the uppermost foil electrode 2221 of the plurality of foil electrodes 2221 provided on the lower end part 222 of the bushing 220 mounted on the outside of the conductor wire 210 from being exposed to the vapor refrigerant g, the lower end of the predetermined range R1 is located over the height (the top end height) of the uppermost foil electrode 2221.

That is, the environment where the foil electrodes 2221 provided for the electric field mitigation are exposed is maintained constantly into the liquid refrigerant.

Further, the upper end of the predetermined range R1 becomes the lower end of the electric heater 500. That is, so as to prevent the liquid surface Is from being increased over the lower end height of the electric heater 500, it is desirable to control the liquid level Is. If the electric heater 500 is located lower than the liquid surface Is, the heat generated from the electric heater 500 being operated is not used for the vaporization of the liquid refrigerant I on the liquid surface Is, just increasing the temperature of the liquid refrigerant beneath the liquid surface Is.

So as to adjust the liquid level Is at the predetermined range R1 through the control of the electric heater 500, it is necessary to accurately determine the location of the liquid refrigerant I contained in the refrigerant container 300.

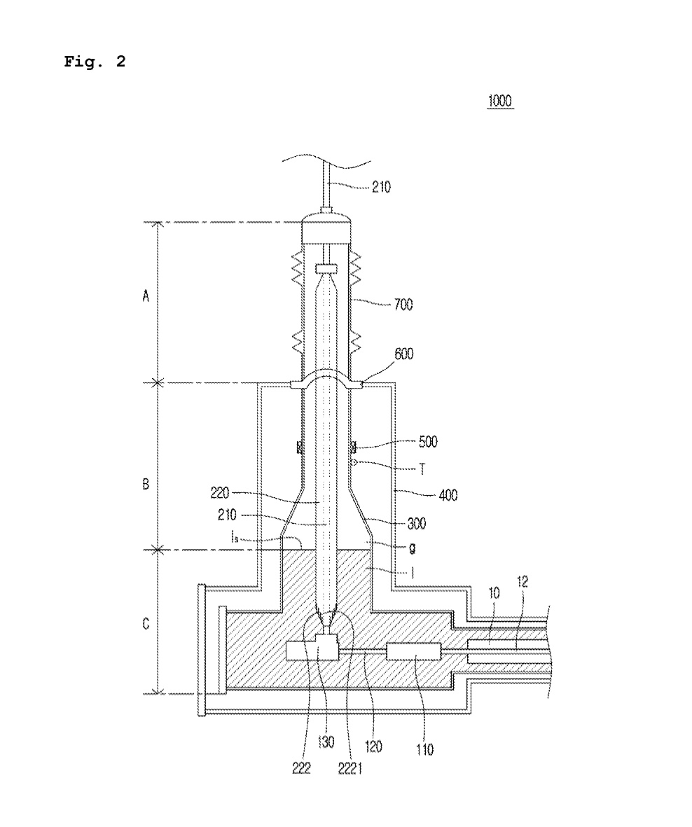

FIG. 2 is a sectional view showing a terminal apparatus of a superconducting device according to a second embodiment of the present invention, wherein the parts that have been already explained in FIG. 1 will be not explained again for the brevity of the description.

The terminal apparatus 1000 of the superconducting device according to the second embodiment of the present invention further includes a sensing unit mounted on the cryogenic temperature part C or the temperature gradient part B to sense the temperature of the cryogenic temperature part C and the temperature gradient part B. The sensing unit is formed of a temperature sensor T.

The temperature sensor T is mounted on the refrigerant container 300 for sensing the surface temperature of the refrigerant container 300 or the temperature of the refrigerant contained in the refrigerant container 300. Further, the sensor T is located adjacent to the electric heater 500.

The sensor T is attached to the refrigerant container 300 for sensing the surface temperature of the refrigerant container 300 or directly measure the temperature of the liquid refrigerant or vapor refrigerant contained in the refrigerant container 300.

In the second embodiment of the present invention as shown in FIG. 2, the sensor T is mounted on the surface of the refrigerant container 300 for sensing the surface temperature of the refrigerant container 300.

The reason why the sensor T is located adjacent to the electric heater 500 is to accurately operate the electric heater 500 in accordance with the liquid level Is determined by the temperature of the refrigerant container 300 sensed through the sensor T.

Further, the terminal apparatus 1000 of the superconducting device according to the second embodiment of the present invention includes a controller (not shown) for controlling the electric heater 500 in accordance with the liquid level Is based on the sensing signal of the sensing unit.

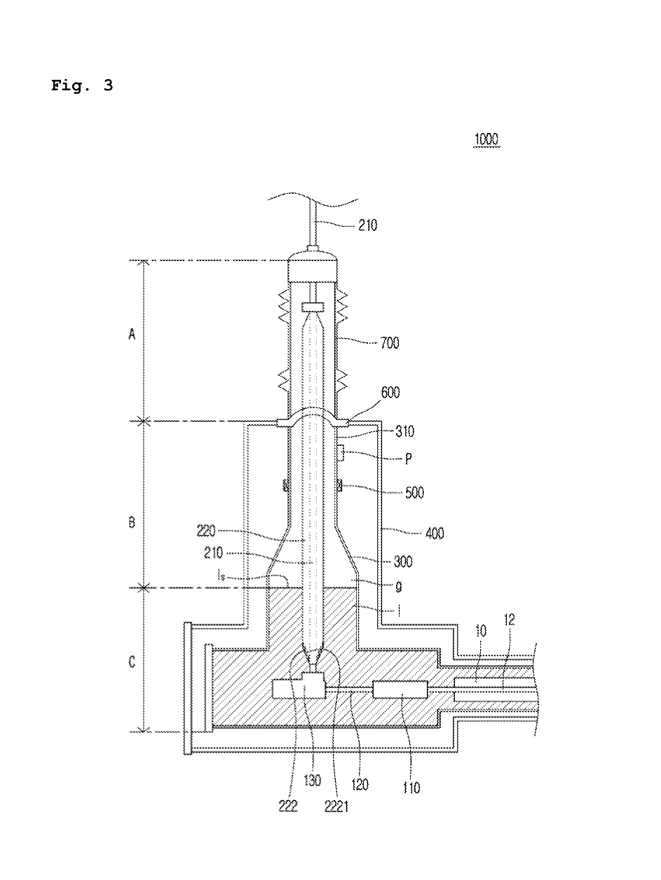

FIG. 3 is a sectional view showing a terminal apparatus of a superconducting device according to a third embodiment of the present invention, wherein the parts that have been already explained in FIG. 1 will be not explained again for the brevity of the description.

The terminal apparatus 1000 of the superconducting device according to the third embodiment of the present invention further includes a pressure sensor P as a sensing unit mounted on the refrigerant container 300 to sense the pressures of the refrigerants contained in the refrigerant container 300.

In the same manner as the temperature sensor T, the pressure sensor P senses the pressure of the vapor refrigerant g contained in the temperature gradient part B to recognize the liquid level Is of the liquid refrigerant I.

For example, the pressure of the vapor refrigerant g is sensed, and if the sensed pressure is lowered, it is determined that the liquid surface Is of the liquid refrigerant I is raised. In the same manner as the method for determining the liquid level Is of the liquid refrigerant I in accordance with the temperature of the refrigerant, the liquid level Is in accordance with the pressure of the vapor refrigerant g is experimentally sensed, and the sensed value is data-based for determining the pressure of the vapor refrigerant g on the basis of the pressure sensor P, thereby determining the liquid surface Is of the liquid refrigerant I.

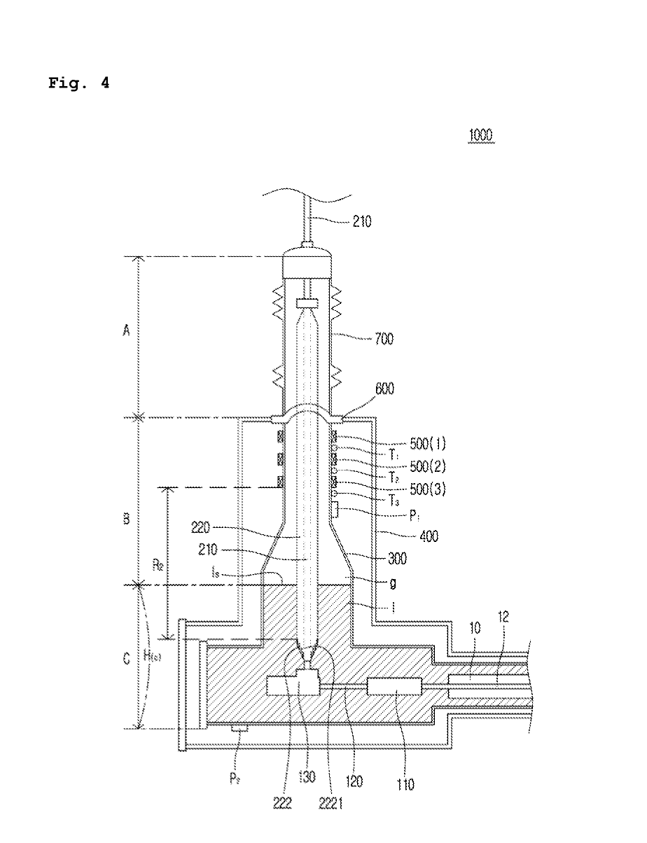

FIG. 4 is a sectional view showing a terminal apparatus of a superconducting device according to a fourth embodiment of the present invention, wherein the parts that have been already explained in FIG. 1 will be not explained again for the brevity of the description.

The terminal apparatus 1000 of the superconducting device according to the fourth embodiment of the present invention further includes a plurality of electric heaters 500 as the liquid surface adjusting unit adapted to artificially adjust the liquid level Is.

In more detail, the terminal apparatus 1000 of the superconducting device as shown in FIG. 4 has first to third electric heaters 500(1), 500(2) and 500(3) mounted on the outer peripheral surface of the refrigerant container 300.

The first to third electric heaters 500(1), 500(2) and 500(3) are mounted spaced apart from each other at different heights of the temperature gradient part B of the refrigerant container 300.

Further, first to third temperature sensors T1, T2 and T3 are mounted adjacent to the first to third electric heaters 500(1), 500(2) and 500(3).

The first to third temperature sensors T1, T2 and T3 are attached to different positions of the refrigerant container 300 for sensing the surface temperature of the refrigerant container 300, that is, the surface temperature of the refrigerant container 300 in accordance with the heights of the temperature gradient part B of the refrigerant container 300.

Accordingly, in the forth embodiment of the present invention, the first to third electric heaters 500(1), 500(2) and 500(3) and the first to third temperature sensors T1, T2 and T3 are sequentially arranged in turn in accordance with the height of the temperature gradient part B of the refrigerant container 300.

If the first to third electric heaters 500(1), 500(2) and 500(3) and the first to third temperature sensors T1, T2 and T3 are arranged in turn, the first to third temperature sensors T1, T2 and T3 can sense the temperatures of the refrigerant container 300 at which they are mounted, thereby sensing the temperature of the refrigerant container 300 in accordance with the temperature gradient of the vapor refrigerant g contained in the temperature gradient part B.

Like this, the plurality of temperature sensors are mounted spaced apart from each other at the different heights of the temperature gradient part B, and the temperatures sensed by the temperature sensors by position are monitored in accordance with time, so that if the sensed temperature by the given temperature sensor is drastically lowered or raised at a specific time point, it is determined that the liquid surface Is is passed through the inner surface of the refrigerant container 300 to which the given temperature sensor is attached at the specific time point and is thus raised or lowered.

Of course, the height of the liquid surface Is is accurately determined through a first equation or a second equation as will be discussed later, but even if just the temperature sensors are provided, the liquid level Is can be somewhat sensed through the observation of the temperature changes in accordance with the time by the region of the temperature gradient part B.

Further, the first to third electric heaters 500(1), 500(2) and 500(3) can be operated together or independently of each other so as to rapidly and accurately adjust the liquid level Is in accordance with the temperature information sensed by the respective temperature sensors.

If the first to third electric heaters 500(1), 500(2) and 500(3) are at the same time operated, a heating value per unit time is optimized to rapidly adjust the liquid level Is of the liquid refrigerant I.

Further, any one of the first to third electric heaters 500(1), 500(2) and 500(3) is used as a main liquid level controlling unit, and the other two electric heaters are used as auxiliary liquid level controlling units.

For example, the first electric heater 500(1) among the first to third electric heaters 500(1), 500(2) and 500(3) may be operated always or alone as a main electric heater, and the second and third electric heaters 500(2) and 500(3) are operated as the auxiliary liquid level controlling units.

If the liquid level Is inside the refrigerant container 300 is drastically raised, accordingly, the temperature gradient sensed through the first to third temperature sensors T1, T2 and T3 is increased, and in this case, the first to third electric heaters 500(1), 500(2) and 500(3) are at the same time operated to optimize the heating value per unit time, thereby rapidly controlling the liquid level Is of the liquid refrigerant I.

On the contrary, if the liquid level Is inside the refrigerant container 300 is slowly raised, the temperature gradient sensed through the first to third temperature sensors T1, T2 and T3 is decreased, and in this case, one of the first to third electric heaters 500(1), 500(2) and 500(3) is operated, and the other electric heaters are stopped.

In this case, the first electric heaters 500(1) provided on the uppermost position (area) of the refrigerant container 300 is used as the main electric heater, and the second and third electric heaters 500(2) and 500(3) are used as the auxiliary electric heaters.

The reason why the first electric heaters 500(1) provided on the uppermost position of the refrigerant container 300 is used as the main electric heater is to prevent the liquid surface Is from approaching the sealing member 600 sealing the top end of the refrigerant container 300, and further, the first electric heaters 500(1) provided on the uppermost position of the refrigerant container 300 is located at a position easily preventing the sealing member 600 or the O-ring mounted together with the sealing member 600 from being overcooled.

Even if the liquid level Is is raised, it rarely approaches the sealing member 600, so that if the uppermost electric heater is used as the main electric heater, the main electric heater is primarily operated to directly heat the vapor refrigerant g, thereby decreasing the liquid level Is of the liquid refrigerant.

Further, in the forth embodiment of the present invention, pressure sensors are provided to sense the pressures of the refrigerants contained in the refrigerant container 300.

Unlike the third embodiment of the present invention as shown in FIG. 3, the forth embodiment of the present invention as shown in FIG. 4 includes first and second pressure sensors P1 and P2 mounted on the temperature gradient part B and the cryogenic temperature part C of the refrigerant container 300 for sensing the pressures of the vapor refrigerant g and the liquid refrigerant I contained therein.

That is, the first pressure sensor P1 is mounted on the temperature gradient part B of the refrigerant container 300 for sensing the pressure of the vapor refrigerant g contained therein, and the second pressure sensor P2 is mounted on the cryogenic temperature part C of the refrigerant container 300 for sensing the pressure of the liquid refrigerant I contained therein.

The reason why the two pressure sensors P1 and P2 are provided is to calculate the difference between the pressures sensed by the respective pressure sensors.

The second pressure sensor P2 senses the pressure of the liquid refrigerant I contained in the lowermost area of the cryogenic temperature part C of the refrigerant container 300, and if the differences or deviations of the pressures of the vapor refrigerant g by region on the temperature gradient part B are small, the difference ΔP between the pressure of the vapor refrigerant g and the pressure of the liquid refrigerant I sensed by the first pressure sensor P1 and the second pressure sensor P2 can be understood through the first equation as follows:

pressure difference ΔP=liquid refrigerant density(p)*acceleration of gravity(g)*liquid surface height of liquid refrigerant(H(c)) (First Equation)

Accordingly, the liquid surface height of liquid refrigerant (H(c)) which determines the liquid level of the liquid refrigerant can be determined by the second equation as follows:

liquid surface height of liquid refrigerant(H(c))=pressure difference ΔP/(liquid refrigerant density(p)*acceleration of gravity(g)) (Second Equation)

As shown in FIG. 3, one pressure sensor can be provided for sensing the pressure of the vapor refrigerant g, so that the liquid level Is is directly determined in accordance with the sensed pressure of the vapor refrigerant g, but as shown in FIG. 4, the plurality of pressure sensors can be provided to determine the pressure difference ΔP over the whole height of the liquid refrigerant, so that the liquid level Is of the liquid refrigerant I is more accurately determined.

The terminal apparatus 1000 of the superconducting device according to the fourth embodiment of the present invention has the electric heaters for adjusting the liquid level Is of the liquid refrigerant I and makes use of the method for sensing the temperature of the refrigerant container 300 or the pressure of the refrigerant as the material data for adjustment of the location of the liquid refrigerant.

As shown in FIG. 4, both of the temperature sensor and the pressure sensor as the sensing unit for sensing the temperature or pressure can be mounted to determine the liquid level Is of the liquid refrigerant I in accordance with the sensed temperature and pressure.

Further, in the fourth embodiment of the present invention as shown in FIG. 4, the plurality of electric heaters 500 is selectively operated to maintain the liquid surface Is of the liquid refrigerant I within a predetermined range R2.

In this case, so as to prevent the uppermost foil electrode 2221 of the plurality of foil electrodes 2221 provided on the lower end part 222 of the bushing 220 located on the outside of the conductor wire 210 from being exposed to the vapor refrigerant g due to the decrease of the liquid surface Is, the lower end of the predetermined range R2 is located over the height of the uppermost foil electrode 2221, and the upper end of the predetermined range R2 becomes the lower end of the third electric heater 500(3) located at the lowermost position among the plurality of electric heaters.

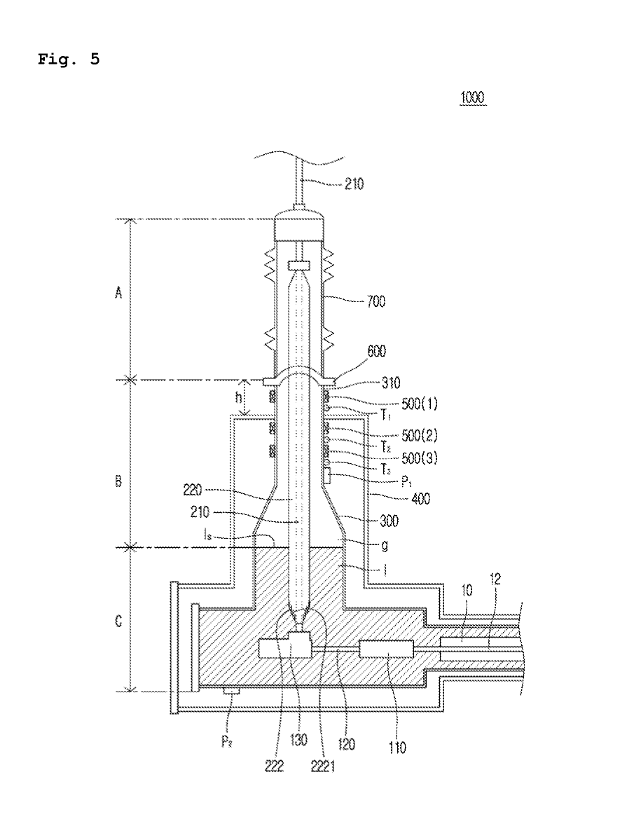

FIG. 5 is a sectional view showing a terminal apparatus of a superconducting device according to a fifth embodiment of the present invention, wherein the parts that have been already explained in FIGS. 1 to 4 will be not explained again for the brevity of the description.

In the same manner as the terminal apparatus 1000 of the superconducting device as shown in FIG. 4, the terminal apparatus 1000 according to the fifth embodiment of the present invention further includes first to third electric heaters 500(1), 500(2) and 500(3) mounted spaced apart from each other at different heights of the temperature gradient part B of the refrigerant container 300 and first to third temperature sensors T1, T2 and T3 mounted adjacent to the first to third electric heaters 500(1), 500(2) and 500(3) for sensing the surface temperatures of the refrigerant container 300 in accordance with the heights of the temperature gradient part B to which they are attached.

Further, the forth embodiment of the present invention includes first and second pressure sensors P1 and P2 adapted for sensing the pressures of the vapor refrigerant g and the liquid refrigerant I contained in the refrigerant container 300. The first pressure sensor P1 is mounted on the temperature gradient part B of the refrigerant container 300 for sensing the pressure of the vapor refrigerant g contained therein, and the second pressure sensor P2 is mounted on the cryogenic temperature part C of the refrigerant container 300 for sensing the pressure of the liquid refrigerant I contained therein.

The terminal apparatus 1000 according to the fifth embodiment of the present invention as shown in FIG. 5 does not have any member adapted to divide the cryogenic temperature part C and the temperature gradient part B from each other. If the liquid surface Is of the liquid refrigerant I is raised abnormally, it reaches the sealing member 600 dividing the room temperature part A and the temperature gradient part B and sealing the temperature gradient part B. If the liquid refrigerant I being at the cryogenic temperature state approaches the sealing member 600, the tightness or durability of the sealing member 600 or the O-ring thereof may be damaged. So as to maintain the liquid surface Is of the liquid refrigerant I contained in the refrigerant container 300 within a predetermined range, accordingly, a part of the refrigerant container 300 is exposed to allow heat intrusion or heat absorption under external environments to be artificially conducted on a partial region of the upper part of the temperature gradient part B of the refrigerant container 300.

In the terminal apparatus 1000 according to the fifth embodiment of the present invention, the vacuum container 400 surrounds the refrigerant container 300 in such a manner to allow a part of the region (indicated by a reference numeral 310) beneath the top end of the refrigerant container 300 to be exposed to the outside.

In this case, the region beneath the top end of the refrigerant container 300 means the region beneath the top end of the refrigerant container 300 where the sealing member 600 is mounted, which is referred to as ‘the region 310 beneath the top end of the refrigerant container 300’.

If the region 310 beneath the top end of the refrigerant container 300 is exposed to the outside, that is, to the room temperature environment, heat transfer or heat intrusion may be generated from a relatively higher temperature outside environment than the refrigerant being at the cryogenic temperature state.

Under the above-mentioned structure, a partial region of the upper part of the refrigerant container 300, that is, the upper end region thereof, which is not covered by the vacuum container 400, is exposed to the room temperature environment.

If the region 310 beneath the top end of the upper part of the refrigerant container 300 is exposed to the room temperature, direct heat intrusion into the vacuum container 400 may be generated at the room temperature environment.

Through such artificial heat intrusion, the heat of the vapor refrigerant g inside the corresponding region is absorbed to cause the liquid surface Is to be decreased, thereby preventing the liquid surface Is of the liquid refrigerant I from approaching the sealing member 600 or the O-ring.

The terminal apparatus 1000 according to the fifth embodiment of the present invention has the electric heaters adapted to artificially decrease the liquid surface Is of the liquid refrigerant I, but even in case where the electric heaters are not operated, the increase of the liquid surface Is can be prevented by the heat intrusion through the region 310 to a degree beneath the top end of the upper part of the refrigerant container 300.

Accordingly, even in the case where the terminal apparatus 1000 according to the fifth embodiment of the present invention has the electric heaters, so as to minimize the operations of the electric heaters, it is configured to permit the region 310 beneath the top end of the refrigerant container 300 to be exposed to the outside of the vacuum container 400.

The refrigerant used for cooling the superconductor is nitrogen, and since the boiling point of nitrogen is −196° C., the vaporization of the liquid refrigerant I and the decrease of the liquid surface Is can be conducted through the heat absorption caused by just the exposure of the partial region of the upper part of the refrigerant container 300 to the room temperature environment.

That is, the heat transmitted to the refrigerant container 300 through the exposure of the partial region of the upper part of the refrigerant container 300 to the room temperature environment can be used for the vaporization process of the liquid refrigerant I around the liquid surface Is.

The height h of the region 310 beneath the top end of the refrigerant container 300 exposed to the outside of the vacuum container 400 is proportional to the surface area of the region 310 beneath the top end of the refrigerant container 300, and the surface area exposed to the room temperature environment is proportional to the heating value transmitted to the refrigerant per unit time. Accordingly, the height h of the region 310 beneath the top end of the refrigerant container 300 is determined in consideration of the temperature of the external environment to adjust the liquid surface Is of the liquid refrigerant I to be located at a range between the lower end part of the bushing 222 surrounding the conductor wire 210 and the sealing member 600. Of course, in case where the liquid surface Is approaches the sealing member 600, the tightness may be deteriorated, and therefore, the height h has a sufficient distance from the underside surface of the sealing member 600.

If the region 310 beneath the top end of the refrigerant container 300 is exposed to the outside to any height, the number of electric heaters mounted on the refrigerant container 300, the operating time of the electric heaters, or the number of times of operation can be reduced.

In the fifth embodiment of the present invention as shown in FIG. 5, the first electric heater 500(1) located at the uppermost position among the first to third electric heaters 500(1), 500(2) and 500(3) may be operated always or alone as a main electric heater, and the second and third electric heaters 500(2) and 500(3) are operated as the auxiliary liquid level controlling units.

In the fifth embodiment of the present invention as shown in FIG. 5, the first electric heater 500(1) is provided on the region 310 beneath the top end of the refrigerant container 300 exposed to the outside, so that the region 310 beneath the top end of the refrigerant container 300 can rapidly decrease the liquid surface Is of the liquid refrigerant I in such a manner to vaporize the liquid refrigerant I on the liquid surface contained in the refrigerant container 300 through the natural heat intrusion and the heating conducted by the electric heaters.

Further, if the electric heater is mounted on the region 310 beneath the top end of the refrigerant container 300 exposed to the outside, it is convenient to perform the maintenance of the electric heater, for example, the repairing or exchange upon malfunction.

If the plurality of electric heaters is mounted, accordingly, at least one electric heater is desirably mounted on the region 310 beneath the top end of the refrigerant container 300 exposed to the outside, so that the heat intrusion from the room temperature environment can be performed therethrough.

That is, as the main liquid level controlling unit having long operating time and many operation times, the electric heater exposed to the outside of the vacuum container 400 rather than the electric heaters provided inside the vacuum container 400 is desirably used.

Further, even in case where only one electric heater is mounted, if a part of the refrigerant container 300 is exposed at the room temperature, the electric heater is desirably mounted on the surface of the refrigerant container 300 exposed to the room temperature, which makes it convenient to perform the maintenance.

However, the method for exposing a part of the refrigerant container 300 to the room temperature environment is not provided necessarily together with the liquid level controlling unit formed of the electric heater, but is auxiliarily adopted.

That is, the method for exposing a part of the refrigerant container 300 to the room temperature environment is applied selectively or together with the liquid level controlling unit in accordance with the climate or weather changes of the area where the terminal apparatus 1000 of the superconducting device is installed.

For example, in the area where the seasons are not changed well, the surface of the refrigerant container 300 exposed to the room temperature environment is optimized to allow the liquid level Is of the liquid refrigerant to reach the predetermined range, thereby minimizing the operation of the electric heater.

Contrarily, if the season change or the temperature change of the room temperature environment by daily temperature range is big, so as to mainly use the electric heater for the liquid surface location adjustment, the surface of the refrigerant container 300 exposed to the room temperature environment is desirably adjusted.

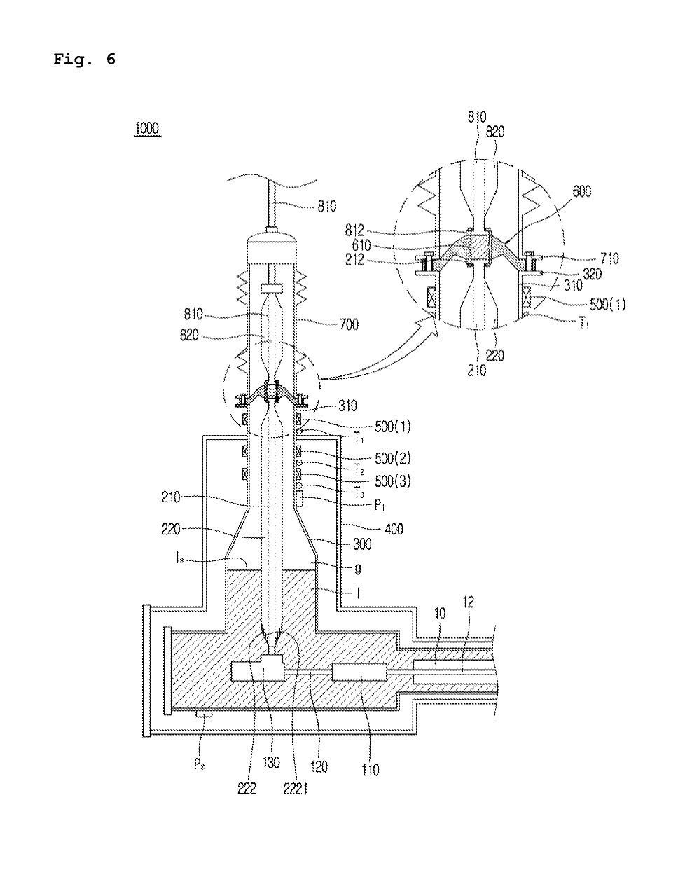

FIG. 6 is a sectional view showing a terminal apparatus of a superconducting device according to a sixth embodiment of the present invention, wherein the parts that have been already explained in FIGS. 1 to 5 will be not explained again for the brevity of the description.

The terminal apparatus 1000 of the superconducting device as shown in FIG. 6 includes: a refrigerant container 300 where a liquid refrigerant is contained in the lower part thereof and a vapor refrigerant is contained above the liquid refrigerant; at least one electric heater 500 mounted on the outer peripheral surface of the refrigerant container 300; at least one temperature sensor T mounted on the outer peripheral surface of the refrigerant container 300 for sensing the temperature of the refrigerant container 300 or the temperature of the refrigerant contained in the refrigerant container 300; a controller (not shown) for controlling the electric heater in accordance with the liquid level based on the sensing signal through the temperature sensor T; a first conductor wire 210 connected to a superconductor of the superconducting device in such a manner to have the lower part submerged into the liquid refrigerant in the refrigerant container 300 and the upper part extended to the upper part of the refrigerant container 300 in which the vapor refrigerant is contained; a sealing member 600 for sealing the top end of the refrigerant container 300; a second conductor wire 810 detachably connected to the first conductor wire 210 by the sealing member 600 in such a manner to be extended upwardly; and a room temperature part housing 700 detachably mounted on the sealing member 600 to surround the second conductor wire 810 and having insulating oil or insulating gas contained therein.

In the same manner as the terminal apparatus 1000 of the superconducting device as shown in FIGS. 4 and 5, the terminal apparatus 1000 according to the sixth embodiment of the present invention further includes: first to third electric heaters 500(1), 500(2) and 500(3) mounted spaced apart from each other at different heights of the temperature gradient part B of the refrigerant container 300; first to third temperature sensors T1, T2 and T3 mounted adjacent to the first to third electric heaters 500(1), 500(2) and 500(3) for sensing the surface temperatures of the refrigerant container 300 in accordance with the heights of the temperature gradient part B to which they are attached; and first and second pressure sensors P1 and P2 adapted for sensing the pressures of the vapor refrigerant g and the liquid refrigerant I contained in the refrigerant container 300.

The first pressure sensor P1 is mounted on the temperature gradient part B of the refrigerant container 300 for sensing the pressure of the vapor refrigerant g contained therein, and the second pressure sensor P2 is mounted on the cryogenic temperature part C of the refrigerant container 300 for sensing the pressure of the liquid refrigerant I contained therein.

In the sixth embodiment of the present invention as shown in FIG. 6, the first electric heater 500(1) located at the uppermost position among the first to third electric heaters 500(1), 500(2) and 500(3) may be operated always or alone as a main electric heater, and the second and third electric heaters 500(2) and 500(3) are operated as the auxiliary liquid level controlling units.

In the sixth embodiment of the present invention as shown in FIG. 6, the first electric heater 500(1) is mounted on the region 310 beneath the top end of the refrigerant container 300 exposed to the outside, so that the region 310 beneath the top end of the refrigerant container 300 can rapidly decrease the liquid surface Is of the liquid refrigerant I through the natural heat intrusion and the heating conducted by the electric heaters.

In the preferred embodiments of the present invention as shown in FIGS. 1 to 5, the conductor wire 210 connected to the superconductor of the superconducting device is passed through the sealing member 600 and extended to the room temperature part A.

That is, the terminal apparatus 1000 of the superconducting device, as shown in FIGS. 1 to 5, is divided into the room temperature part A, the temperature gradient part B and the cryogenic temperature part C by region and has one conductor wire 210, so that the room temperature part A and the temperature gradient part B are not easily separated from each other.

Accordingly, the terminal apparatus 1000 of the superconducting device, as shown in FIGS. 1 to 5, does not have any separation in the conductor wire 210, so that it may be difficult in the connection with an external device or connection box, large volume is needed, and an insulation weakness part is increased.

So as to remove the above-mentioned problems, in the sixth embodiment of the present invention as shown in FIG. 6, the room temperature part A is detachably mounted on the temperature gradient part B.

That is, the room temperature part A is detachably mounted on the temperature gradient part B on the boundary of the sealing member 600.

The detachable mounting of the room temperature part A on the temperature gradient part B cannot be carried out by one conductor wire that is extended along the cryogenic temperature part C, the temperature gradient part B and the room temperature part A in such a manner to be drawn to the room temperature environment, as shown in FIGS. 1 to 5.

Accordingly, in the sixth embodiment of the present invention as shown in FIG. 6, the first conductor wire 210 is disposed on the cryogenic temperature part C and the temperature gradient part B, that is, on the refrigerant container 300, and the second conductor wire 810 is located at the room temperature part housing 700 constituting the room temperature part A and mounted on the boundary of the sealing member 600. Further, a method is provided for connecting the first conductor wire 210 and the second conductor wire 810 at the sealing member 600.

That is, the two separated conductor wires 210 and 810 are provided on the terminal apparatus 1000 of the superconducting device, and the sealed refrigerant container 300 by the sealing member 600 and the room temperature part A can be separated from each other.

The sealing member 600 of the terminal apparatus 1000 of the superconducting device according to the sixth embodiment of the present invention includes a conductive connector 610 adapted to couple the first conductor wire 210 and the second conductor wire 810 to each other and to electrically connect them to each other.

The sealing member 600 is made of a material like epoxy, and the conductive connector 610 is made of a conductive metal material penetrating up and down into the sealing member 600.

The first conductor wire 210 and the second conductor wire 810 are coupled to the underside and top surfaces of the conductive connector 610 by coupling members like bolts.

Further, the top end periphery 320 of the refrigerant container 300 and the bottom end periphery 710 of the room temperature part housing 700 have flange structures so that the top end periphery 320 of the refrigerant container 300, the periphery of the sealing member 600, and the bottom end periphery 710 of the room temperature part housing 700 are coupled to each other by coupling members like bolts.

The second conductor wire 810, which is located inside the room temperature part A and coupled to the sealing member 600, has a bushing 820, and the room temperature part housing 700 contains insulating oil or insulating gas therein.

Accordingly, the second conductor wire 810 and the room temperature part housing 700 constituting the room temperature part A are separable from the sealing member 600, easily connected with another external device, and easy in the change of the intended usage of the terminal box, without having any separate connection box.

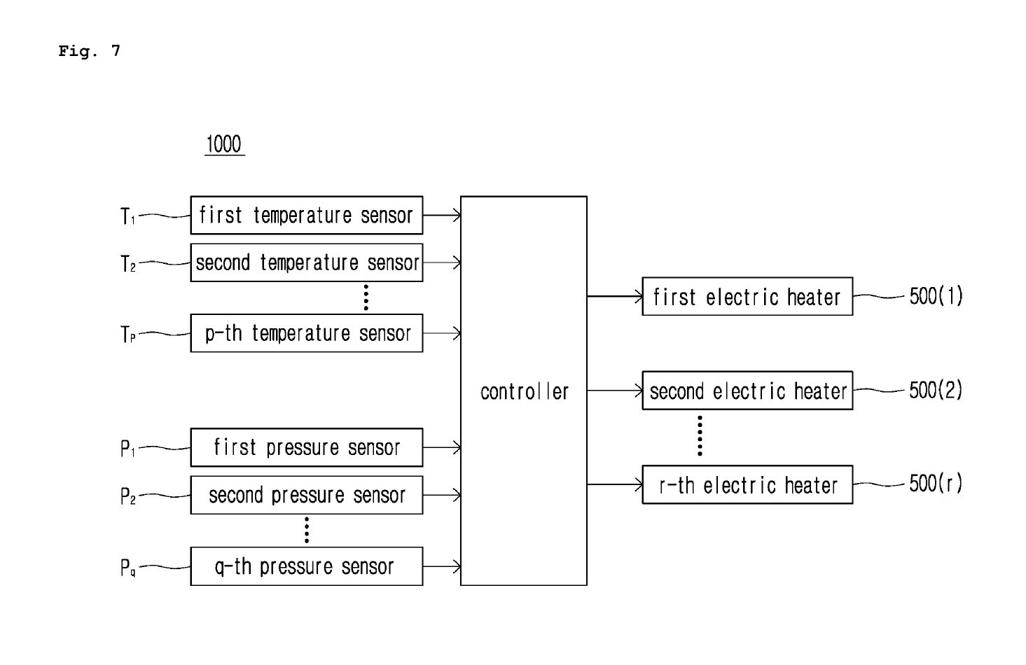

FIG. 7 is a block diagram showing the terminal apparatus of the superconducting device according to the present invention.

As shown in FIG. 7, the terminal apparatus 1000 of the superconducting device according to the preferred embodiments of the present invention includes at least one temperature sensors and/or at least one pressure sensors.

Further, the terminal apparatus 1000 of the superconducting device according to the preferred embodiments of the present invention includes the controller for controlling the electric heaters in accordance with the liquid level Is based on the sensing signal through the temperature sensors or the pressure sensors.

As shown in FIG. 7, the terminal apparatus 1000 of the superconducting device according to the preferred embodiments of the present invention includes p temperature sensors T1, T2, . . . and Tp and q pressure sensors P1, P2, . . . and Pq, so that r electric heaters 500(1), 500(2), . . . and 500(r) are controlled in accordance with the liquid level Is of the liquid refrigerant determined by the sensed temperatures and pressures through the temperature sensors and the pressure sensors.

The control variables of the electric heaters 500(1), 500(2), . . . and 500(r) through the controller are operating start points, operating time, and heating values per unit time of the electric heaters 500(1), 500(2), . . . and 500(r).

The heating values per unit time of the electric heaters 500(1), 500(2), . . . and 500(r) as the control variables of the controller are controlled by adjusting the size of the electric energy supplied to the heaters.

Furthermore, if the region 310 beneath the top end of the refrigerant container 300 is exposed to the outside of the vacuum container 400, the controller operates the electric heater exposed to the outside of the vacuum container 400 as a main electric heater, thereby allowing the operating time of the main electric heater longer than that of the other electric heaters, making the operating start point of the main electric heater more rapid than those of the other electric heaters, or making the heating value per unit time of the main electric heater larger than those of the other electric heaters.

The plurality of electric heaters 500(1), 500(2), . . . and 500(r) is provided, and if they have the same output as each other, the heating values per unit time that are capable of being generated from the electric heaters in the terminal apparatus of the superconducting device are determined upon the number of electric heaters being operated among the plurality of electric heaters. If the outputs of the respective electric heaters are adjustable, however, the heating values per unit time can be finely adjusted through the output adjustment of the respective electric heaters.

The controller operates the electric heaters 500(1), 500(2), . . . and 500(r) independently, and as mentioned above, controls them in such a manner as where at least one electric heater among the electric heaters 500(1), 500(2), . . . and 500(r) has the operating start point, the operating time, and the heating value per unit time different from those of the other electric heaters.

As described above, the terminal apparatus of the superconducting device according to the preferred embodiments of the present invention has the electric heaters as the liquid level controlling units, thereby artificially controlling the liquid level of the liquid refrigerant.

Additionally, the terminal apparatus of the superconducting device according to the preferred embodiments of the present invention is capable of accurately determining the liquid level of the liquid refrigerant in the refrigerant container in accordance with the temperature or pressure sensed by the temperature sensor or the pressure sensor, thereby accurately determining the location changes of the liquid surface according to the operation of the electric heater and precisely controlling the liquid level of the liquid refrigerant.

Further, the terminal apparatus of the superconducting device according to the preferred embodiments of the present invention is configured to allow a part of the upper end region of the refrigerant container to be exposed to the room temperature environment, thereby somewhat alleviating the problems caused by the increase of the liquid surface.

Furthermore, the terminal apparatus of the superconducting device according to the preferred embodiments of the present invention adjusts the area of the refrigerant container exposed to the outside of the vacuum container in accordance with the environment on which the terminal apparatus is installed, thereby optimizing the height of the liquid surface of the liquid refrigerant in accordance with the room temperature environment.

In addition, the terminal apparatus of the superconducting device according to the preferred embodiments of the present invention is capable of alleviating the increase of the liquid surface, thereby improving the tightness or durability of the sealing member or the O-ring.

Moreover, the terminal apparatus of the superconducting device according to the preferred embodiments of the present invention allows the room temperature part tube and the conductor wire located at the inside of the room temperature part tube, constituting the room temperature part, to be detachably mounted on the sealing member for sealing the refrigerant container, thereby enabling the room temperature part to be easily connected with another external device and to be easy in the change of the intended usage of the terminal box, without having any separate connection box.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention.

What is claimed is:

1. A terminal apparatus of a superconducting device, comprising:
a refrigerant container having a cryogenic temperature part formed in the lower part thereof, the cryogenic temperature part containing a liquid refrigerant therein, and a temperature gradient part formed above the cryogenic temperature part, the temperature gradient part containing a vapor refrigerant having temperature gradient therein;
at least one liquid level controlling unit provided to the refrigerant container;
at least one sensing unit provided to the refrigerant container for sensing the temperature or pressure of the refrigerant container or the temperature or pressure of the refrigerant contained in the refrigerant container;
a controller for controlling the liquid level controlling unit in accordance with the liquid level based on the sensing signal of the sensing unit;
a room temperature part housing divided with the refrigerant container, having insulating oil or insulating gas contained therein and forming a room temperature part; and
a conductor wire connected to a superconductor of the superconducting device in the liquid refrigerant in the refrigerant container and extended to the room temperature part housing.

2. The terminal apparatus of a superconducting device according to claim 1, wherein the sensing unit comprises a temperature sensor mounted on the refrigerant container.

3. The terminal apparatus of a superconducting device according to claim 2, wherein the temperature sensor senses the temperature of the surface of the refrigerant container.

4. The terminal apparatus of a superconducting device according to claim 3, wherein the temperature sensor is provided plurally, and at least one temperature signals of the plural sensors is mounted on the temperature gradient part of the refrigerant container.

5. The terminal apparatus of a superconducting device according to claim 1, wherein the sensing unit comprises a pressure sensor mounted on the refrigerant container.

6. The terminal apparatus of a superconducting device according to claim 5, wherein two or more pressure sensors are mounted on different positions from each other.

7. The terminal apparatus of a superconducting device according to claim 6, wherein at least one pressure sensor is mounted on the cryogenic temperature part and the temperature gradient part, respectively, for sensing the pressures of the liquid refrigerant and vapor refrigerant contained in the refrigerant container.

8. The terminal apparatus of a superconducting device according to claim 7, wherein the pressure sensor mounted on the cryogenic temperature part is located at a position where the pressure of the liquid refrigerant existing on the lowest area of the cryogenic temperature part is sensed.

9. The terminal apparatus of a superconducting device according to claim 8, wherein the controller determines the liquid level of the liquid refrigerant on the basis of the pressure difference sensed by the pressure sensors mounted on the cryogenic temperature part and the temperature gradient part.

10. The terminal apparatus of a superconducting device according to claim 1, wherein the refrigerant container is sealed by a sealing member, and the room temperature part housing is mounted on the sealing member.

11. The terminal apparatus of a superconducting device according to claim 1, further comprising a vacuum container for surrounding the refrigerant container in such a manner to allow the region beneath the top end of the refrigerant container to be exposed.

12. The terminal apparatus of a superconducting device according to claim 1, wherein the liquid level controlling unit comprises at least one electric heaters mounted on the outer peripheral surface of the refrigerant container.

13. The terminal apparatus of a superconducting device according to claim 12, wherein the electric heaters are mounted spaced apart from each other at different heights of the temperature gradient part.

14. The terminal apparatus of a superconducting device according to claim 12, wherein the controller operates the electric heaters to maintain the liquid surface of the liquid refrigerant in the refrigerant container within a predetermined range.

15. The termination structure of a superconducting device according to claim 14, wherein the lower end of the predetermined range is located at the height of the foil electrode disposed at the uppermost position among a plurality of foil electrodes mounted on a busing located on the lower portion of the conductor wire.

16. The terminal apparatus of a superconducting device according to claim 14, wherein the upper end of the predetermined range is located at the height of the lower end of the electric heater disposed at the lowermost position among the electric heaters mounted on the temperature gradient part.

17. A terminal apparatus of a superconducting device, comprising:
a refrigerant container containing a liquid refrigerant in the lower part thereof and a vapor refrigerant above the liquid refrigerant;
at least one electric heaters mounted on the refrigerant container;
at least one temperature sensors mounted on the refrigerant container for sensing the temperature of the refrigerant container or the temperature of the refrigerant contained in the refrigerant container;
a controller for controlling the electric heaters in accordance with the liquid level based on the sensing signal through the temperature sensor;
a first conductor wire connected to a superconductor of the superconducting device in such a manner to have the lower part submerged into the liquid refrigerant in the refrigerant container and the upper part extended to the upper part of the refrigerant container in which the vapor refrigerant is contained;
a sealing member for sealing the top end of the refrigerant container;
a second conductor wire detachably connected to the first conductor wire by the sealing member in such a manner to be extended upwardly; and
a room temperature part housing detachably mounted on the sealing member to surround the second conductor wire and having insulating oil or insulating gas contained therein.

18. The terminal apparatus of a superconducting device according to claim 17, wherein the controller operates the electric heaters if the temperature sensed by the temperature sensor is decreased under a predetermined temperature.

19. The terminal apparatus of a superconducting device according to claim 17, wherein the electric heaters are mounted plurally on the outer peripheral surface of the refrigerant container, and the temperature sensors are mounted plurally adjacent to the electric heaters on the outer peripheral surface of the refrigerant container.

20. The terminal apparatus of a superconducting device according to claim 19, wherein the controller operates the electric heaters for the operating start point, operating time, and the heating value per unit time of at least one electric heater among the plural electric heaters to be different from those of the other electric heaters or for the operating start points, operating time, and the heating values per unit time of the electric heaters to be same as each other.

21. The terminal apparatus of a superconducting device according to claim 19, further comprising a vacuum container for surrounding the refrigerant container in such a manner to allow the region beneath the top end of the refrigerant container to be exposed to the outside, thereby allowing the space of the refrigerant container where the liquid refrigerant is contained and a part of the space where the vapor refrigerant is contained to be vacuum-insulated, and wherein at least one electric heater among the electric heaters is mounted on the outer peripheral surface of the refrigerant container exposed to the outside of the vacuum container.

22. The terminal apparatus of a superconducting device according to claim 21, wherein the controller operates the electric heater mounted on the outer peripheral surface of the refrigerant container exposed to the outside of the vacuum container for the operating time thereof to be longer than that of the other electric heaters.

23. The terminal apparatus of a superconducting device according to claim 21, wherein the controller operates the electric heater mounted on the outer peripheral surface of the refrigerant container exposed to the outside of the vacuum container for the operating start point thereof to be more rapid than those of the other electric heaters.

24. The terminal apparatus of a superconducting device according to claim 21, wherein the controller operates the electric heater mounted on the outer peripheral surface of the refrigerant container exposed to the outside of the vacuum container for the heating value per unit time thereof to be larger than those of the other electric heaters.

25. The terminal apparatus of a superconducting device according to claim 17, further comprising at least one pressure sensors mounted on the refrigerant container for sensing the pressure of the liquid refrigerant or the pressure of the vapor refrigerant contained in the refrigerant container.

26. The terminal apparatus of a superconducting device according to claim 25, wherein the pressure sensors are mounted on the position where the liquid refrigerant is contained and the position where the vapor refrigerant is contained for sensing the pressures of the liquid refrigerant and vapor refrigerant, and the controller determines the liquid level of the liquid refrigerant on the basis of the pressure difference sensed by the pressure sensors.

27. The terminal apparatus of a superconducting device according to claim 17, wherein the sealing member comprises a conductive connector disposed at the center part thereof to couple the first conductor wire and the second conductor wire to each other.
